(19) United States
(12) Patent Application Publication
(10) Pub. No.: US 2015/0004824 A1
(43) Pub. Date: Jan. 1, 2015

(54) Dual Inline Memory Module Socket

(71) Applicant: Hewlett-Packard Development Company, L.P., Houston, TX (US)

(72) Inventors: Vincent Nguyen, Houston, TX (US); Binh Nguyen, Houston, TX (US); Melvin K. Benedict, Magnolia, TX (US); Minh H. Nguyen, Katy, TX (US)

(21) Appl. No.: 13/931,286

(22) Filed: Jun. 28, 2013

(51) Int. Cl. H01R 13/629; G01R 31/04

(52) U.S. Cl. CPC H01R 13/629; G01R 31/041
USPC 439/345; 324/538

(57) ABSTRACT

The present disclosure describes, in one example, a dual inline memory module socket. The dual inline memory module socket includes a base to receive a memory module. The base further comprises a first detection pin and a second detection pin. A latch may be coupled to the base and is to electrically couple the first detection pin to the second detection pin in a dosed position to enable a determination that the memory module is properly seated.

### BACKGROUND

In computing, memory generally refers to physical devices used to store programs, sequences of instructions, or data on a temporary or permanent basis. There are different types of memory which have varying operating characteristics. For example, random access memory (RAM) may function at higher speeds, but does not retain data in the absence of power. Read only memory (ROM) may retain data in the absence of power but is much slower relative to RAM.

With respect to RAM, there are, again, multiple types. Dynamic random access memory (DRAM) is a type of RAM that is generally utilized as the main memory in computer systems, DRAM modules may be combined and disposed on a printed circuit board forming a dual inline memory module (DIMM). In various computing systems, these DIMMS may be placed within a DIMM socket The DIMM socket may enable the addition and removal of DIMMs.

### BRIEF DESCRIPTION OF THE DRAWINGS

FIG. 1 is a perspective view of a dual in-line memory module socket in accordance with an example of the present disclosure.

FIG. 2A-B is a view of various components of a dual inline memory module socket in accordance with an example of the present disclosure.

FIG. 3 is a view of various components of a dual in-line memory module socket in accordance with an example of the present disclosure.

FIG. 4 illustrates a diagram of a dual in-line memory module socket in accordance with an example of the present disclosure.

FIG. 5 illustrates a diagram of a dual in-line memory module socket in accordance with an example of the present disclosure.

FIG. 6 illustrates a diagram of a dual in-line memory module socket in accordance with an example of the present disclosure.

FIG. 7 illustrates a diagram of a dual in-line memory module socket in accordance with an example of the present disclosure

FIG. 8 illustrates a block diagram of a system in accordance with an example of the present disclosure.

FIGS. 9-10 illustrate flow diagrams in accordance with venous examples of the present disclosure.

### DETAILED DESCRIPTION

In computing systems, main memory may be incorporated into the system via the use of sockets. A socket, as used herein, is a component attachable to a printed circuit board (PCB) that enables a coupling or decoupling of a component. For example, a dual inline memory module (DIMM) may be incorporated into a computing system to increase main memory, and consequently increase various operating characteristics of the computing system, via a DIMM socket.

While sockets, such as DIMM sockets, facilitate customization of computer systems and enable future upgrades, they may also lead to inadvertent errors. For example, if a DIMM is not properly seated within a DIMM socket, single bit errors, multiple bit errors, or system failure may result. The improper seating of the DIMM within the DIMM socket may be the result of improper installation by a user or environmental effects such as vibrations that dislodge the DIMM.

While the improper seating of a MINI within a computer system may be remedied by adjusting the DIMM, it is often the case that identification of the improper DIMM is an issue. Within server systems, as DIMM sockets proliferate, a single improperly seated DIMM may bring the computer system down and be difficult to identify. These errors may lead to increased warranty costs and a decrease in customer satisfaction due to long outage windows associated with fault DIMM isolation.

For the purposes of determining whether a DIMM is properly seated within a DIMM socket, systems and techniques are disclosed herein, which may monitor detection pins disposed within the DIMM socket. By monitoring the detection pins, identification of improperly seated DIMMS may result.

More specifically, systems and techniques are disclosed for monitoring, via a logic device, detection pins within a DIMM socket. The detection pins may indicate a proper or improper seating based on a position of a latch utilized to secure the DIMM within the DIMM socket. The present disclosure will discuss these systems and techniques with respect to DIMMs formed with dynamic random access memory (DRAM). It is noted, however, that the disclosure is not so limited.

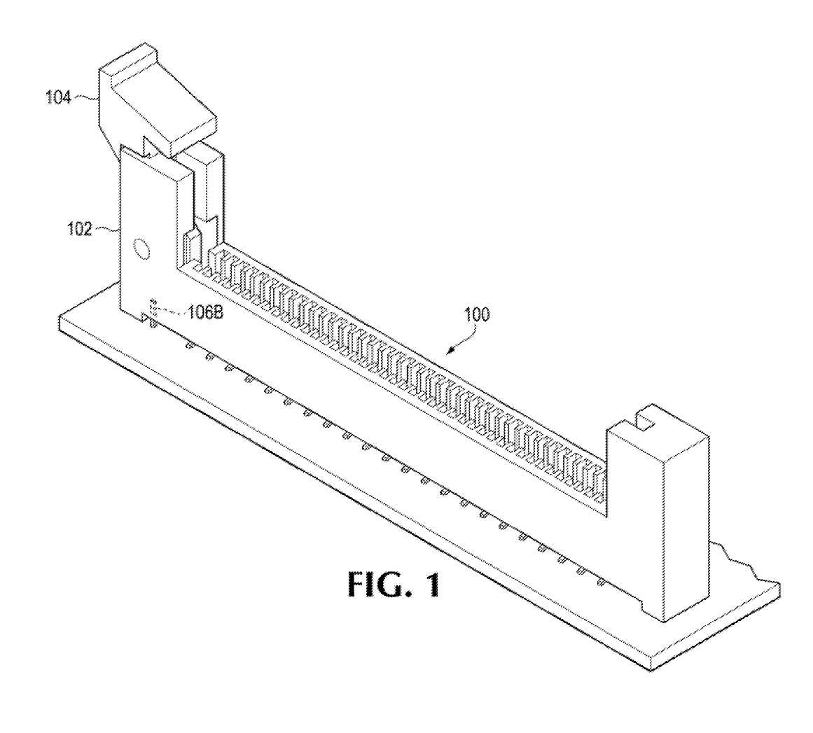

Referring to FIG. 1, a perspective view of a DIMM socket 100 is illustrated in accordance with an example of the present disclosure. The DIMM socket incorporates reliability, availability, and serviceability (RAS) features, such as but not limited to, DIMM seating detection. The DIMM socket 100 comprises a base 102, a latch 104, and a detection pin 106B.

The base 102 may comprise a plurality of pins to interlace with a plurality of contacts on a memory module such as a dual inline memory module (DIMM). The base 102 may be configured for mounting on a printed circuit board (PCB) and interface with traces therein. The base 102 may include one more characteristics to enable use with particular versions of DIMMS such as DDR1, DDR2, DDR3, DDR4, and others.

In addition to the plurality of pins associated with the plurality of contacts on the DIMM, the base 102 may comprise a first detection pin 106B disposed on a first side of a first end of the DIMM socket and a second detection in (not illustrated) disposed on a second side of the first end of the DIMM socket. The first and second detection pins are illustrated more clearly in other figures.

The base 102 may be coupled to a latch 104. The latch 104 may be configured to secure a DIMM within the DIMM socket 100. To secure the DIMM within the DIMM socket 100, the latch 104 may interface with one or more features on the DIMM, such as but not limited to, notches. The latch 104 may electrically couple the first detection pin 106B to the second detection pin when the latch 104 is in a closed position. The latch 104 may decouple the first detection pin 106B from the second detection pin in an open position. In a closed position, the latch 104 may enable a determination that the memory module is properly seated. As used herein properly seated is defined as being seated such that the plurality of pins of the interface with the plurality of contacts of the memory module.

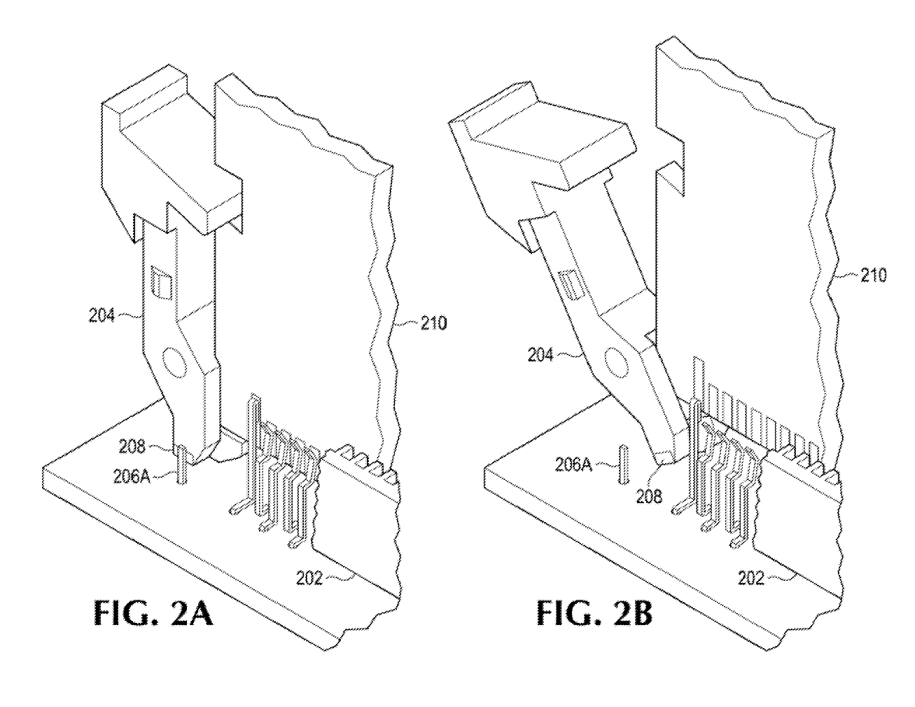

Referring now to FIGS. 2A-8, perspective views of a DIMM socket are illustrated in accordance with various examples. In FIG. 2A, the DIMM socket 200 is illustrated in a dosed position. In FIG. 2B, the DIMM socket 200 is illustrated in an open position. The DIMM socket 200 includes a base 202, a latch 204, which are similar to those described with respect to FIG. 1, a first detection pin 206A, a second detection pin (not illustrated), and a bridge 208.

Referring first to FIG. 2A, the DIMM socket 200 is illustrated in the dosed position, with a DIMM 210 properly seated within the DIMM socket 200. In the closed position, the latch 204 may be vertically oriented such that it is substantially parallel with the DIMM 210. In this position, the bridge 208 may electrically couple the first detection in 206A to the second detection pin. As used herein a bridge is a conductive path configured to electrically couple one pin or contact to another pin or contact.

Referring to FIG. 2B, the DIMM socket 200 is illustrated in the open position, with the DIMM 210 improperly seated within the DIMM socket. In the open position, the latch 204 may pivot about a pivot point to provide a force on a bottom of the DIMM 210 to extract the DIMM. Alternatively, in the example where a DIMM is being added, the latch 204 may provide a guide or resting point for DIMM 210.

In the open position, the latch 204 is pivoted away from the first and second detection pins 206A-B, such that the bridge 208 disposed on the latch 204 is moved out of contact. The movement away from the first detection pins 206A-B may open a previously closed circuit. The change in status of the circuit or the open circuit itself may be utilized to determine the improper seating of a DIMM 210.

Referring to FIG. 3 another perspective view is illustrated in accordance with various examples. Similar to FIG. 2A, the DIMM socket 300 is illustrated in a closed position in FIG. 3.

Referring first to FIG. 3, the DIMM socket includes, a base 302, a latch 304, a first detection in 306A, and a second detection pin 306B. In addition, the latch 304 includes a bridge 308 to couple the first detection pin 306A to the second detection pin 306B. The latch 304, bridge 308, and detection pins 306A,B are configured such that in a locked position the continuity between the detection pins 306A,B is sustained. When DIMM socket 300 is in an open position, the latch 304 is rotated about a pivot point such that bridge 308 is moved out of contact with one or both o first and second detection pins 308A,B. In this manner, the continuity is broken and a circuit, as will be discussed in more detail herein, may determine that a DIMM is not seated or improperly seated within the DIMM socket 300.

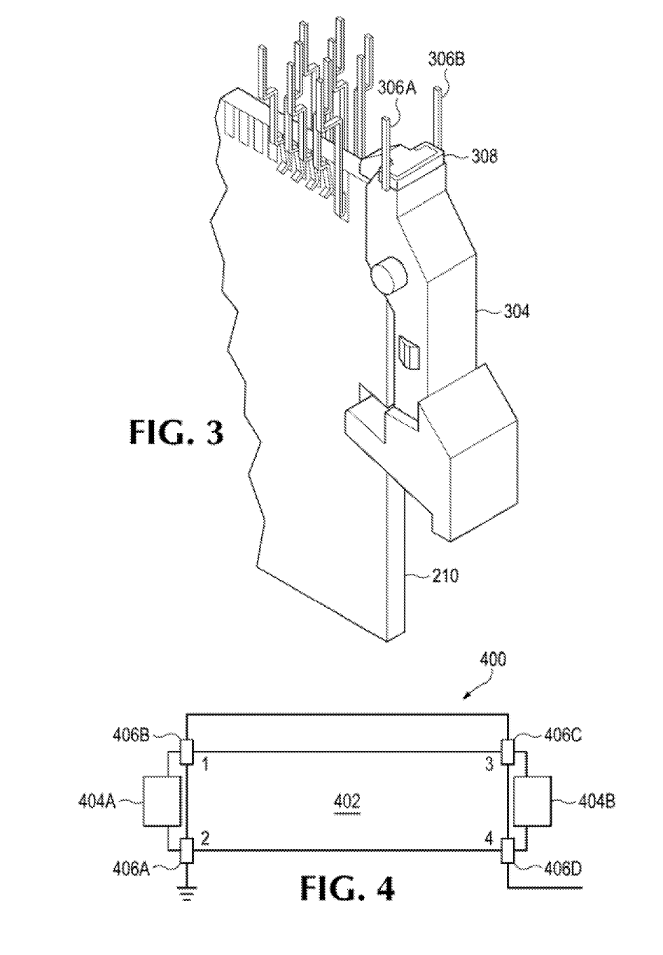

With respect to FIG. 4, a conceptual view of a DIMM socket is illustrated in accordance with an example of the present disclosure. The DIMM socket includes a base 402, a first latch and a second latch 404A-B, and a plurality of detection pins 406A-D. The components illustrated in FIG. 4 may be generally similar those described with reference to the preceding figures.

In the illustrated example, the DIMM socket 400 includes a first detection pin 406A that is coupled to ground, a second detection pin 406B that is coupled to a third detection pin 406C, and a fourth detection 406D that may be coupled to a logic device (not illustrated). In addition, the DIMM socket 400 may include a first latch 404A disposed between the first detection pin 406A and the second detection pin 406B, and a second latch 404B that is disposed between the third detection 406C and the fourth detection pin 406D. The first latch 404A and the second latch 404B both include a bridge not illustrated) that is configured to couple their respective detection pins 406A-D to each other. In other words, the first latch 404A is to electrically couple the first detection pin 406A to the second detection pin 406B in a closed position and the second latch 404B is to electrically couple the third detection in 406C to the fourth detection pin 406D in a closed position.

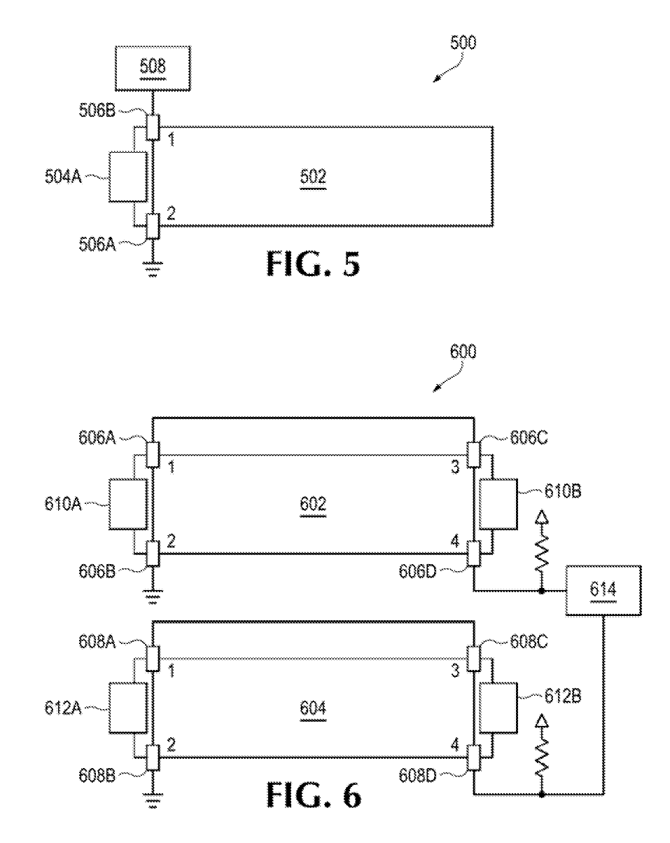

Referring to FIG. 5, a system incorporating a DIMM socket as described in previous figures is illustrated in accordance with an example of the present disclosure. FIG. 5 includes a DIMM socket 500 and a logic device 508. The DIMM socket 500 may include a base 502, a latch 504, and a plurality of detection pins 506A-B.

Logic device 505 may be a program logic device such as but not limited to a complex programmable logic device (CPLD), a programmable array logic (PAL), a field programmable gate array (FPGA), an application specific integrated circuit (ASIC), or another device capable of differentiating between high and low signals.

In the illustrated Figure, the logic device 508 is coupled to a detection pin 506B of DIMM socket 500. The DIMM socket 500 further includes another detection pin 506A coupled to a ground voltage, a latch 504 disposed between the two detection pins 506A-B, and a base 502. The plurality of detection pins 506A-B and the latch 504 are to couple the plurality of detection pins 506A-B to each other in a closed position and decouple the plurality of detection pins 506A-B from each other in an open position.

The logic device 508 coupled to the DIMM socket 500 is to determine whether the DIMM socket is in the closed position or the open position based on the ground voltage. For example, in a closed position latch 504 will electrically couple first detection pin 506A to second detection pin 506B effectively coupling a corresponding pin of the logic device 508 to a ground voltage.

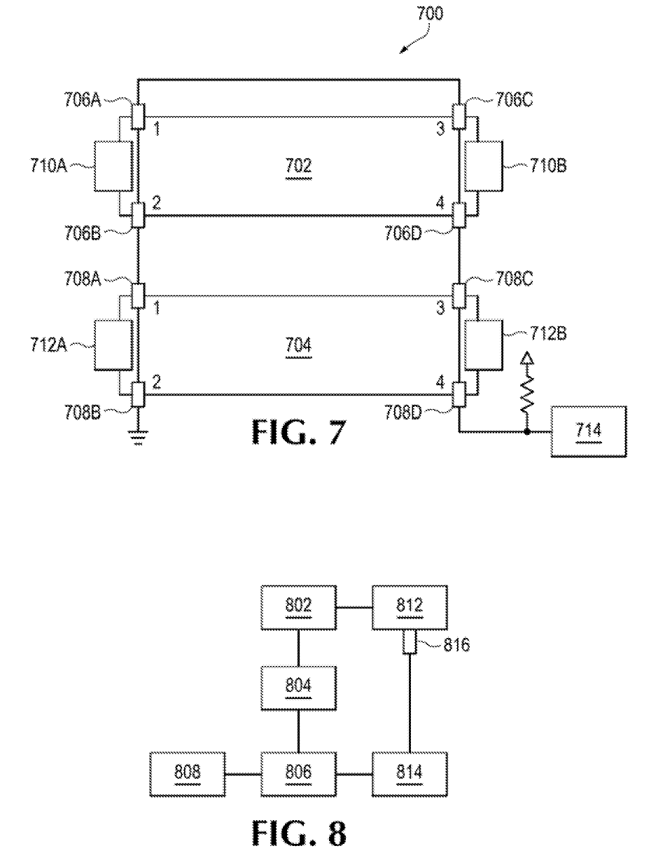

Referring to FIGS. 6 and 7, additional examples are illustrated in accordance with the present disclosure. In FIG. 6, a first DMA socket 602 and a second DIMM socket 604 are illustrated with detection pins 606A-D and 608A-D, and latches 610A-B and 612A-B, respectively.

With reference to DIMM socket 602, detection pin 606B is coupled to ground, detection pin 606A is coupled to detection pin 606C, and detection pin 606D is coupled to a logic device 614 and a voltage 616. DIMM socket 604 includes a similar configuration with detection in 608B coupled to ground, detection pin 608A coupled to detection pin 608C, and detection pin 608D coupled to the logic device 614 and a voltage 616. In this configuration the first DIMM socket 602 and the second DIMM socket 604 are each monitored by the logic device 612. Consequently, the logic device 612 may determine whether the second DIM socket is in the close position or the open position independent of the other DIMM socket.

In FIG. 7, a cascaded structure is illustrated in accordance with an example of the present disclosure. In FIG. 7, the plurality of detection pins 706A-D, 708A-D are electrically coupled together when latches 710A-B and 712A-B are in a closed position. In other words, detection pin 708B is coupled to ground and detection pin 708A, via latch 712A, detection pin 708A coupled to detection pin 706A. Detection pin 706B is coupled, via latch 710A, to detection pin 706A is coupled to detection pin 706B. Detection pin 706B is coupled o detection pin 706D, via latch 710B, and detection pin 706D is coupled to detection pin 708C. Detection pin 708C is coupled, via latch 712B to detection pin 708D. In turn, detection pin 708D is coupled to a high voltage 716 and a pin of the logic device 714.

In this manner, the logic device may determine whether the first DIMM socket 702 and the second DIMM socket 704 are concurrently in the closed position. While the logic device 714 may not be able to differentiate which DIMM socket is experiencing an improperly seated DIMM, the logic device may provide a subset of DIMM sockets which should be inspected. In a cascaded structure, the logic device may utilize one pin for any number of DIMM sockets. The use of fewer pins may decrease cost and complexity of the logic device and the overall system.

FIG. 8 is a block diagram of a system in accordance with an example of the present disclosure. The system of FIG. 8 includes a central processing unit (CPU) 802, an Input(Output (I/O) controller 804, a baseboard management controller (BMC) 806, a read only memory (ROM) including a basic input/output system (BIOS) 808, a logic device 814, and a DIMM, socket 812 including a plurality of defection pins 816.

The CPU 802 is a hardware component within the system that carries out instructions of a computer program. The CPU 802 may be configured to execute instructions such as those of the BIOS 808 to initiate the system. In addition the CPU 802 is coupled to one or more DIMM sockets 812 to enable efficient access to system memory.

The I/O controller 804 may facilitate 110 functions such as universal serial bus (USB), audio, the ISA bus, interrupt controllers, the baseboard management controller 806, and others.

The baseboard management controller (BMC) 808 may be a component configured to enable out of band management of the system. Out of band management, as used herein, enables a system administrator to monitor and manage a system and other network equipment via a remote console independent of a power state or status of an operating system. The baseboard management controller 808 may be an intelligent platform management interface (IPMI).

The DM socket 812 and the logic device 814 are generally similar to the DIMM sockets described with respect to the preceding figures. The DIMM socket 812 is coupled to the CPU 802 and the detection pins of the DIMM socket 812 are coupled to the logic device 812.

In one example, the CPU 802 may execute the BIOS 808. During execution of the BIOS 808, the CPU 802 may communicate with the logic device 814 to determine whether or not the DIMM socket 812 is in a dosed position. In response to a determination that the DIMM socket 812 is in an open state, a warning or indication may be presented to a user. In case of DIMM socket 812 is in a closed state, the BIOS 808 continues POST process to initialize the memory in DIMM socket 812 to be included in the pool of system memory resources.

In another example, the BMC 806 may communicate with the logic device 814 to determine whether or not the DIMM socket 812 is in en open or dosed position. The BMC 806 may communicate with the logic device 814 while the system is in an unpowered state and independent of an operating system. The BMC 806 may enable out of band monitoring of whether the DIMM socket is in a dosed position.

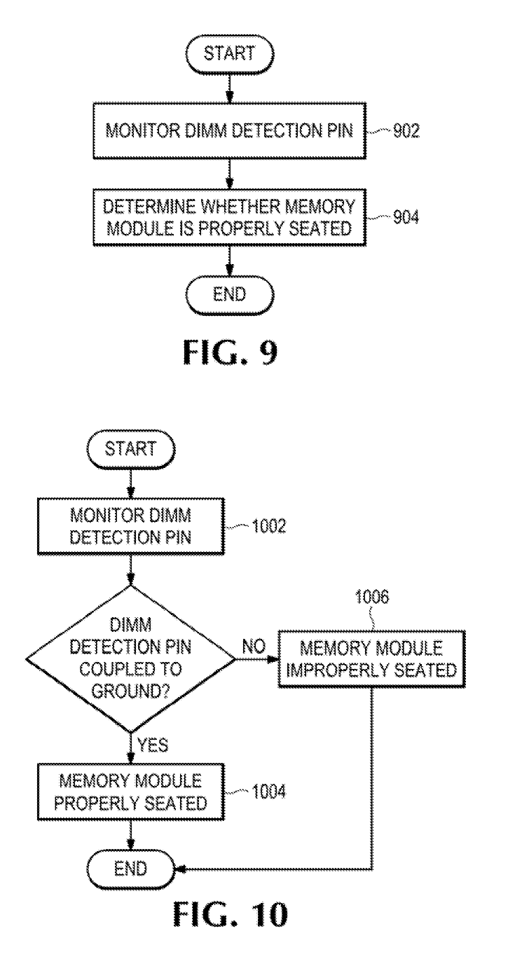

Referring to FIGS. 9-10, flow diagrams are illustrated in accordance with examples of the present disclosures. The flow diagrams illustrate techniques that may be utilized in conjunction with the systems and devices described in the preceding Figures. While the flow diagrams illustrate various elements in a particular order, the flow diagrams are not intended to limit the disclosure to such an implementation. Rather, other combinations and orders of elements are contemplated.

Referring to FIG. 9, a the flow diagram may begin and progress to 902 where a logic device may monitor a DIMM detection in of a DIMM socket. The DIMM detection pin may be coupled to a plurality of DIMM detection pins as described with reference to FIGS. 1-7.

Upon monitoring of the DIMM detection pin, the logic device may determine whether a memory module Is properly seated based on the DIMM detection pin. The method may then end or the faulty DIMM may be mapped out from system memory resource depending on the memory populated configurations.

Referring to FIG. 10, a more detailed flow diagram is illustrated in accordance with various examples. The flow diagram may begin and progress to 1002 where a logic device may monitor a DIMM detection pin, in various examples, monitoring the DIMM detection pin may comprise monitoring a voltage a high voltage on the DIMM detection pin for a transition to a ground voltage. The DIMM detection pin may he coupled in a cascaded fashion to one or more DIMM sockets.

Upon monitoring the DIMM detection pin at 1002, the logic device may determine that the module is property seated in response to a DIMM detection pin being coupled to ground at 1004. Alternatively, the logic device may determine that the memory module is improperly seated in response to the DIMM detection pin remaining at a high voltage at 1006. The method may then end or the faulty DIMM may be mapped out from system memory resource depending on the memory populated configurations.

While a limited number of examples have been disclosed herein, those skilled in the art, having the benefit of this disclosure, will appreciate numerous modifications and variations therefrom. For example, as previous discussed it is expressly contemplated that various methodologies described herein may be implemented within individual components, for example, the DRAM itself. It is intended that the appended claims cover all such modifications and variations.

What is claimed is:

1. A dual in-line memory module (DIMM) socket, comprising:
a base to receive a memory module, wherein the base comprises a first detection pin disposed on a first side of a first end of the DIMM socket and a second detection pin disposed on a second side of the first end of the DIMM socket; and
a latch coupled to the base, wherein the latch is to electrically couple the first detection pin to the second detection pin in a closed position to enable a determination that the memory module is properly seated.

2. The DIMM socket of claim 1, wherein the base further comprises a third detection pin disposed on the first side of a second end of the DIMM and a fourth detection pin disposed on the second side of the second end of the DIMM.

3. The DIMM socket of claim 2, further comprising:
a second latch coupled to the base, wherein the second latch is electrically couple the third detection pin to the fourth detection pin in a closed position to enable the determination that the memory module is properly seated.

4. The DIMM socket of claim 1, wherein one of the first detection pin or the second detection pin is to be coupled to ground to enable the determination that the memory module is properly seated.

5. The DIMM socket of claim 1, wherein the base is to receive a double data rate 4 (DDR4) memory module.

6. A system, comprising:
a dual inline memory module (DIMM) socket comprising a plurality of detection pins and a latch to couple the plurality of detection pins to each other in a dosed position and decouple the plurality of detection pins from each other in an open position, wherein at least one of the detection pins is coupled to a ground voltage; and
a logic device coupled to the DIMM socket, wherein the logic device is determine whether the DIMM socket is in the closed position or the open position based on the ground voltage.

7. The system of claim 6, wherein the DIMM socket comprises a second latch disposed at a distal end opposite the latch; and
wherein the latch and the second latch are to couple the plurality of detection pins to each other in a closed position.

8. The system of claim 6, further comprising:
a processor to execute a basic input output operating system (BIOS), wherein the processor is to communicate with the logic device to determine whether the DIMM socket is in the closed position.

9. The system of claim 6, further comprising:
a second DIMM socket comprising a plurality of detection pins and a latch to couple the plurality of detection pins of the second DIMM socket to each other in a closed position and decouple the plurality of pins of the second DIMM socket from each other in an open position.

10. The system of claim 9, wherein the logic device is to determine whether the second DIMM socket is in the closed position or the open position independently of the DIMM socket.

11. The system of claim 9, wherein the plurality of detection pins of the DIMM socket are coupled to the plurality off detection pins of the second DIMM socket when the DIMM socket and the second DRAM socket are both in a closed position; and
wherein the logic device is to determine whether the DIMM socket and the second DIMM socket are concurrently in the closed position.

12. The system of claim 6, further comprising:
a baseboard management controller to communicate with the logic device to enable out of band monitoring of whether the DIMM socket is in the closed position.

13. A method, comprising:
monitoring, via a logic device, a dual inline memory module (DIMM) detection pin;
determining, via the logic device, whether a memory module is properly seated based on the DIMM detection pin.

14. The method of claim 13, wherein determining whether the memory module is property seated comprises:
determining, via the logic device, the memory module is properly seated in response to the DIMM detection pin being coupled to a ground voltage.

15. The method of claim 13, wherein determining whether the memory module is properly seated comprises:
determining, via the logic device, the memory module is improperly seated in in response to the DIMM detection pin being coupled to as voltage.
